(19) United States
(12) Patent Application Publication
(10) Pub. No.: US 2024/0107864 A1
(43) Pub. Date: Mar. 28, 2024

(54) FOLDABLE DEVICE WITH BEZEL LOCATED CAMERA

(71) Applicant: Google LLC, Mountain View, CA (US)

(72) Inventors: Michael J. Lombardi, South Barrington, IL (US); Joseph Allore, Mountain View, CA (US); Sangsoo Park, Mundelein, IL (US)

(21) Appl. No.: 18/264,377

(22) PCT Filed: Jun. 29, 2021
(86) PCT No.: PCT/US2021/039591

§ 371 Date: Aug. 4, 2023

Related U.S. Application Data
(60) Provisional application No. 63/151,267, filed on Feb. 19, 2021.

(51) Int. Cl. H10K 59/90; G06F 1/16; H10K 59/80

(52) U.S. Cl. CPC H10K 59/90; G06F 1/1618; H10K 59/80; H10K 2102/311

(57) ABSTRACT

A hinge assembly defining a first axis and a second axis; a first assembly rotatably connected to the hinge assembly about the first axis; a second assembly rotatably connected to the hinge assembly about the second axis, wherein, when the folding device is fully opened about the hinge assembly, an inner surface of the first assembly is coplanar with an inner surface of the second assembly; a flexible continuous display spanning an inner surface of the first assembly and an inner surface of the second assembly; and a camera having an aperture located in a bezel of the second assembly that borders the flexible continuous display.

This application claims the benefit of U.S. Provisional Patent Application No. 63/151,267, filed 19 Feb. 2021, the entire contents of which is incorporated herein by reference.

### BACKGROUND

Devices that include displays may be referred to as display devices. In general, it may be desirable to increase a size of a display (e.g., the area on which images are displayed) as much as possible. However, increasing the size of a display may make the device that includes the display large and unwieldy. For instance, devices with larger displays may not fit in pockets, bags, and the like. One way to increase the size of a display without unduly increasing the size of the device is to make the device collapsible such that the display can be folded (e.g., in half).

### SUMMARY

In general, aspects of this disclosure are directed to a folding device that includes a camera in a bezel of a foldable continuous display. A folding device may include at least two assemblies (e.g., panels) and a mechanism configured to allow the assemblies to be moved into a collapsed state in which the device is considered closed and an expanded state in which the device is considered open. When the device is in the expanded state, the display may be visible and may cover at least a portion of an inner surface of all of the assemblies. As such, the device may be considered to be a continuous display (i.e., because it continues across a boundary between the assemblies). By utilizing such a folding device, the device may include a display with a relatively large length and/or width (e.g., display area) without overly increasing a length and/or width of the device when in the collapsed state. In this way, the “pocketability” of large-screen portable devices may be improved.

However, some folding mechanisms may introduce one or more disadvantages. As one example, while sizes of some dimensions (e.g., height or width) of the device may be reduced (e.g., relative to a non-folding device with equivalent screen size), incorporation of a folding mechanism may undesirably increase other dimensions of the device. For instance, some folding mechanisms, such as those that enable an apex of a continuous display to reside within a hinge assembly, may increase a size of a dimension parallel to a folding axis(es) (e.g., due to arms connecting assemblies to a hinge assembly being moved out from “under” the continuous display). This increase in other dimensions of the device may result in a larger bezel (e.g., relative to a folding device with a different folding mechanism).

Devices may include one or more cameras to capture image data. In some examples, a device may include a camera located under a viewable area of a display (e.g., under a portion of the display that would otherwise include pixels). For instance, the display may include a hole (e.g., may be referred to as a hole-punch display) via-which light passes before detection by an image sensor of the camera. However, integrating a camera under a viewable area of a foldable display may present drawbacks relative to integrating a camera under a viewable area of a non-foldable display. Integrating a camera into an otherwise small bezel may be similarly undesirable. For instance, it may not be desirable to increase a size of a bezel to accommodate a camera.

In accordance with one or more aspects of this disclosure, a foldable device may include continuous display and a camera located in a bezel of the continuous display. For instance, where a foldable device includes a mechanism that enables an apex of a continuous display to reside within a hinge assembly when the foldable device is closed, the foldable device may include camera located in a bezel of the continuous display. In this way, the foldable device may include a camera in a bezel without significantly increasing a size of the bezel. Also in this way, difficulties and complications with under display cameras in foldable devices may be avoided.

As one example, a folding computing device includes a hinge assembly defining a first axis and a second axis; a first assembly rotatably connected to the hinge assembly about the first axis; a second assembly rotatably connected to the hinge assembly about the second axis, wherein, when the folding device is fully opened about the hinge assembly, an inner surface of the first assembly is coplanar with an inner surface of the second assembly; a flexible continuous display spanning an inner surface of the first assembly and an inner surface of the second assembly; and a camera having an aperture located in a bezel of the second assembly that borders the flexible continuous display.

The details of one or more examples are set forth in the accompanying drawings and the description below. Other features, objects, and advantages of the disclosure will be apparent from the description and drawings, and from the claims.

### BRIEF DESCRIPTION OF DRAWINGS

FIG. 1 is a schematic diagram illustrating a folding device with a camera integrated into a bezel of a continuous display, in accordance with one or more aspects of this disclosure.

FIG. 2 is an angled view illustrating a folding device with a camera integrated into a bezel of a continuous display, in accordance with one or more aspects of this disclosure.

FIGS. 3A-3C are schematic diagrams illustrating cross sections of a folding device with a camera integrated into a bezel of a continuous display, in accordance with one or more aspects of this disclosure.

FIGS. 4A-4F are schematic diagrams illustrating a layering of components that results in a camera integrated into a bezel of a continuous display, in accordance with one or more aspects of this disclosure.

FIG. 5A is a schematic diagram illustrating an assembled camera integrated into a bezel of a continuous display of a folding device, in accordance with one or more aspects of this disclosure.

FIG. 5B is a schematic illustrating a cross-section along line A-A of FIG. 5A, in accordance with one or more aspects of this disclosure.

FIG. 5C is a schematic illustrating a cross-section along line B-B of FIG. 5A, in accordance with one or more aspects of this disclosure.

FIG. 5D is an enlargement of area C of FIG. 5B, in accordance with one or more aspects of this disclosure.

FIG. 6 is a schematic illustrating a cross section similar to FIG. 5D, in accordance with one or more aspects of this disclosure.

FIG. 7 is a schematic diagram illustrating an assembled camera integrated into a bezel of a continuous display of a folding device, in accordance with one or more aspects of this disclosure.

### DETAILED DESCRIPTION

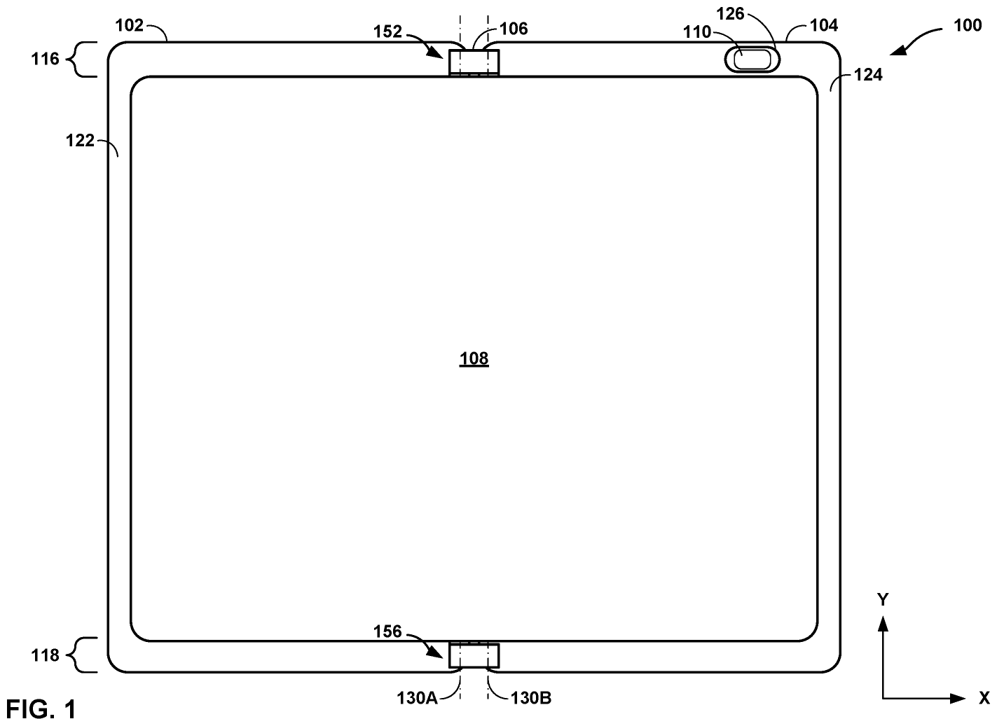

FIG. 1 is a schematic diagram illustrating a folding device with a camera integrated into a bezel of a continuous display, in accordance with one or more aspects of this disclosure. Examples of folding device 100 include foldable mobile computing devices such as foldable smart phones, foldable tablets, foldable e-readers, foldable gaming systems, and any other foldable portable device that includes a display.

As shown in FIG. 1, folding device 100 includes a first assembly 102, a second assembly 104, a hinge assembly 106, continuous display 108, and camera 110. Hinge assembly 106 may define a first axis 130A and a second axis 130B. First assembly 102 and second assembly 104 may be configured to rotate about first axis 108 and second axis 110, respectively, to allow first assembly 102 and second assembly 104 to move into a collapsed state and an expanded state. For instance, first assembly 102 may be rotatably connected to hinge assembly 106 about first axis 130A and second assembly 104 may be rotatably connected to hinge assembly 106 about second axis 130B. In the example of FIG. 1, folding device 100 is shown in the expanded state (e.g., a fully-open state). As can be seen in FIG. 1, when folding device 100 is fully opened about hinge assembly 106, an inner surface of first assembly 102 may be coplanar with an inner surface of second assembly 104.

Continuous display 108 may be capable of rendering data into images viewable by a user of device 100. For example, continuous display 108 may include a matrix of pixels that are individually controllable. Examples of continuous display 108 include, but are not limited to, liquid crystal displays (LCD), light emitting diode (LED) displays, organic light-emitting diode (OLED) displays, micro light-emitting diode (microLED) displays, or similar monochrome or color displays capable of outputting visible information to a user of device 100.

Continuous display 108 may include one or more rigid segments and one or more flexible segments. For instance, continuous display 108 may include one or more rigid segments and one or more flexible segments as described in PCT/US2020/66676 filed Dec. 22, 2020 by Lombardi et al.

In some examples, device 100 may include one or more displays in addition to continuous display 108. For instance, device 100 may include a first additional display on the outer surface of first assembly 102. In some examples, device 100 may further include a second additional display on the outer surface of second assembly 104.

One or more of continuous display 108, the first additional display, and/or the second additional display may be presence-sensitive displays. In some examples, a presence sensitive display may detect an object at and/or near a screen. As one example range, a presence-sensitive display may detect an object, such as a finger or stylus that is within 2 inches or less of the screen. The presence-sensitive display may determine a location (e.g., an (x,y) coordinate) of a screen at which the object was detected. In another example range, a presence-sensitive display may detect an object six inches or less from the screen and other ranges are also possible. The presence-sensitive display may determine the location of the screen selected by a user's finger using capacitive, inductive, and/or optical recognition techniques. In some examples, presence sensitive display also provides output to a user using tactile, audio, or video stimuli.

As shown in FIG. 1, each of first assembly 102 and second assembly 104 may include top bezel 116 and bottom bezel 118. It is understood that the labels “top” and “bottom” are used for convenience and rotation of foldable device 100 will change the relative top and bottom of foldable device 100. In some examples, one or both of first assembly 102 and second assembly 104 may include a side bezel. As one example, first assembly 102 may include a side bezel that, in the reference frame of FIG. 1, would be a left bezel. As another example, second assembly 104 may include a side bezel that, in the reference frame of FIG. 1, would be a right bezel.

Each of first assembly 102 and second assembly 104 may include one or more respective housing components. Example of housing components include, but are not limited to, primary housings, trim housings, and armature housings. As one example, first assembly 102 may include trim housing 122 that may form a portion of one or more of top bezel 116, bottom bezel 118, and, if present, a left bezel. As another example, second assembly 104 may include trim housing 124 that may form a portion of one or more of top bezel 116, bottom bezel 118, and, if present, a right bezel. Collectively, top bezel 116, bottom bezel 118, the left bezel, and the right bezel may constitute a border or perimeter around continuous display 108.

Camera 110 may be configured to capture image data (e.g., to transduce light into electrical signals that represent image data). Camera 110 may include various components such as a lens and an image sensor. Examples of image sensors that may be included in camera 110 include, but are not limited to, a charge-couple device (CCD), and a complementary metal-oxide-semiconductor (CMOS sensor), and/or the like. The image sensor may vary in shape and size. In some examples, the image sensor may be rectangular. Camera 110 may provide image data to one or more other components of foldable device 100, such as processing circuitry (e.g., which may or may not be the same processing circuitry that control images output at continuous display 108).

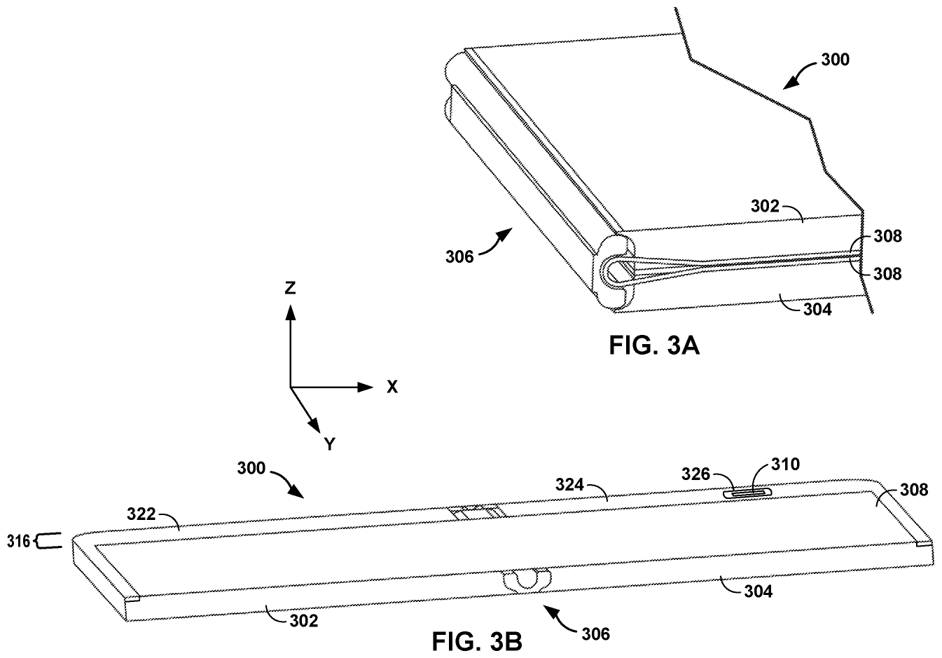

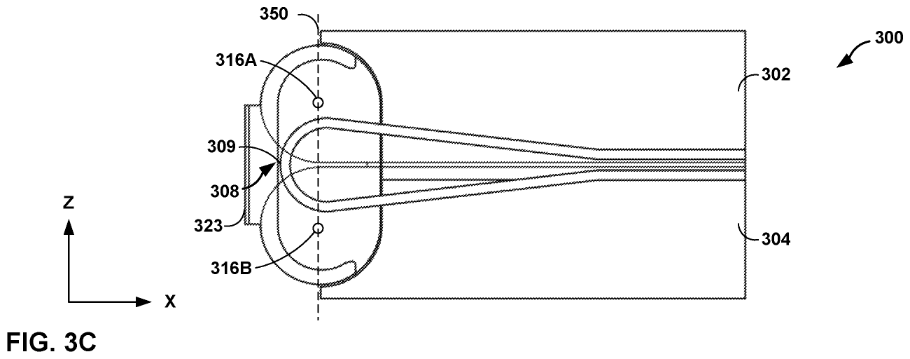

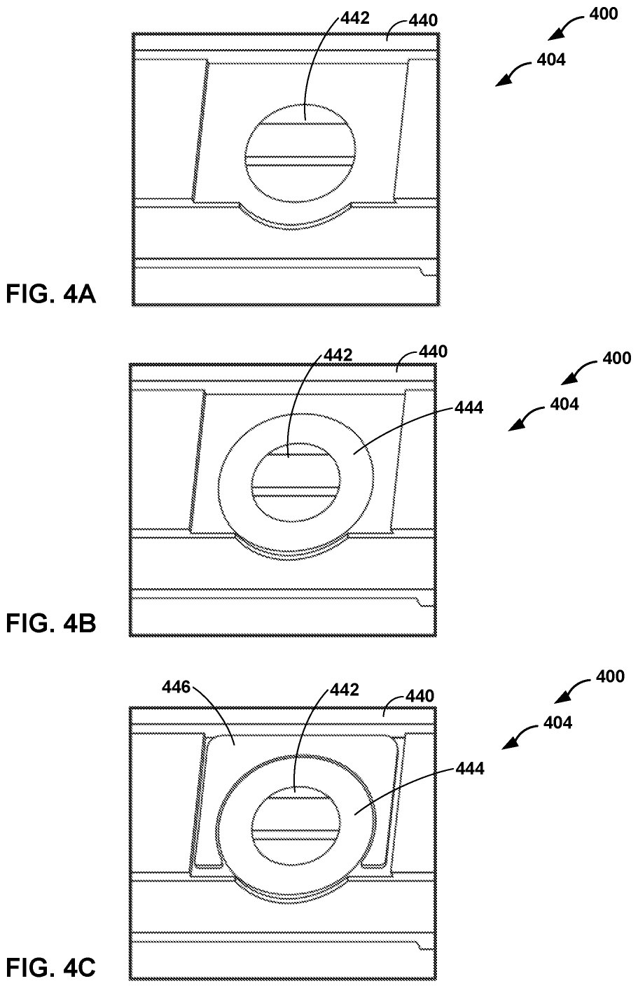

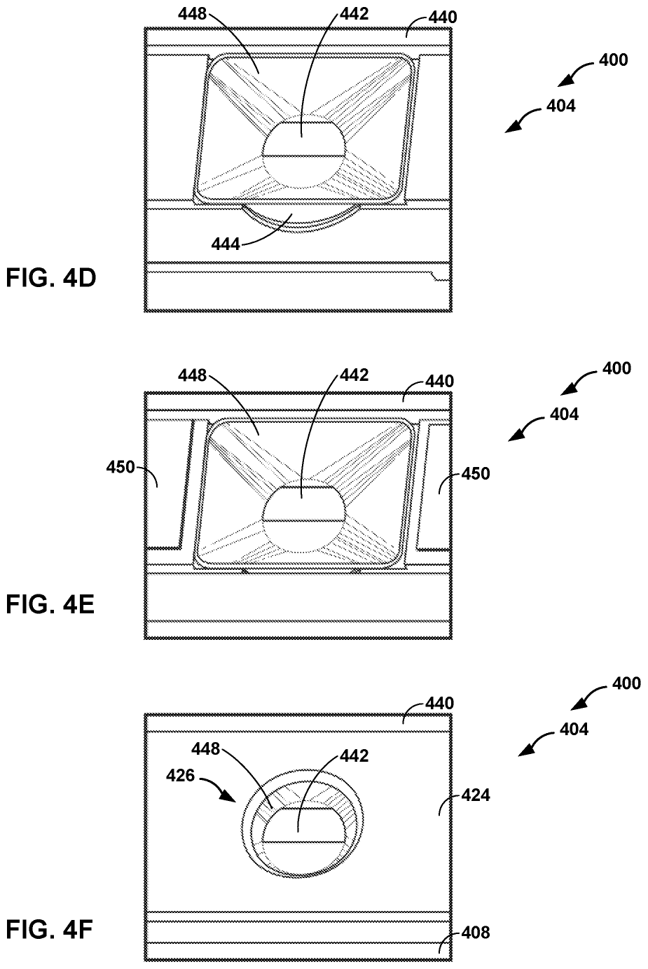

In some examples, hinge assembly 106 may include a cavity into which at least a portion of continuous display 108 may recede when device 100 is fully closed. For instance, as discussed in further detail below, a center region of hinge assembly 106 may be “hollowed out” to receive at least a portion of primary flexible segment 308. As shown in FIGS. 3A, 3B, and 4, when the folding device is fully closed, an apex of the primary flexible segment (e.g., apex 409 of continuous display 408 of FIG. 4) is closer to an outer surface of the hinge assembly (e.g., outer surface 423 of hinge assembly 406 of FIG. 4) than a plane that is parallel to the first axis and a second axis (e.g., plane 450 that is parallel to first axis 416A and second axis 416B). By allowing at least a portion of display 108 may recede when device 100 is fully closed, device 100 may avoid the need for a rotate and slide mechanism In this way, the design of a foldable display device may be simplified.

As discussed above, hinge assembly 106 may include a cavity into which at least a portion of display 108 may recede when folding device 100 is fully closed. By including such a cavity into hinge assembly 106, mechanical components that connect to first assembly 102 and second assembly 104 may be moved (e.g., so as not to obstruct movement of display 108).

Folding device 100 may be extended in a direction parallel to the hinge folding axis (e.g., device 100 may be stretched in the y-axis). In such a design, mechanical components that connect hinge assembly 106 to first assembly 102 and second assembly 104 (e.g., pins, gears, etc.) may be moved into one or both of top hinge region 152 and/or bottom hinge region 156. As such, first assembly 102 and second assembly 104 may each be rotatably connected to top hinge region 152 and bottom hinge region 156. Due to this arrangement, in some examples, the mechanical components that connect hinge assembly 106 to first assembly 102 and second assembly 104 may not be located under (e.g., in the z-axis) display 108. For instance, the mechanical components that connect hinge assembly 106 to first assembly 102 and second assembly 104 may be located under top bezel 116 and/or under bottom bezel 118. As shown in FIG. 1, top bezel 116 may encompass top hinge region 152 and bottom bezel 118 may encompass bottom hinge region 156.

In accordance with one or more aspects of this disclosure, camera 110 may be located in a bezel of continuous display 108. For instance, as shown in FIG. 1, camera 110 may be located (e.g., may have an aperture located) in top bezel 116 that borders continuous display 108. As noted above, top bezel 116 may already have to be enlarged to accommodate top hinge region 152. For instance, a dimension of top bezel 116 parallel to second axis 130B (e.g., in the y-axis) may be greater than or equal to a dimension of top hinge region 152 parallel to second axis 130B. As such, camera 110 may be included within top bezel 116 without having to enlarge top bezel 116 (e.g., in the y-axis). In other words, camera 110 and top hinge region 152 may utilize the same perimeter space such that neither increases the overall size of folding device 100. In this way, difficulties and complications with under display cameras in foldable devices may be avoided without having to enlarge a bezel solely to accommodate a camera.

As discussed above, in some examples, folding device 100 may include trim housing components, such as trim housing 124. In accordance with one or more aspects of this disclosure, a trim housing component may define an opening via which the aperture of camera 110 receives light. For instance, as shown in FIG. 1 trim housing 124 may define opening 126 which the aperture of camera 110 receives light (e.g., which the image sensor of camera 110 transduces into electrical signals). A shape of opening 126 may be selected to create a cosmetic frame surrounding camera 110. Example shapes of opening 126 include, but are not limited to, rectangles, ovals, circles, discorectangles (e.g., stadium or pill shape), and the like. Additionally or alternatively, a dust seal (e.g., dust seal 444) may be applied to still be visible (e.g., to a user of folding device 100). In this way, a lens of camera 110 may be non-decorated (e.g., may be clear and omit ink or other markings that would otherwise create a cosmetic frame).

As noted above, camera 110 may include an image sensor. The image sensor may be configured to capture a rectangular image. In some examples, an aspect ratio of the image sensor may be 16:9, 4:3, 3:2, 1.85:1, or the like. The longer dimension of the image sensor may be perpendicular to the folding axes (e.g., 130A and 130B). For instance, as shown in FIG. 1, camera 110 is illustrated as a rectangle with a longer dimension in the x-axis. The orientation of opening 126 may correspond with an orientation of the image sensor of camera 110. For instance, the shorter dimension of opening 126 is oriented parallel to the folding axes (e.g., 130A and 130B) such that the border of the product outside the display active area is minimized. In this way, no cuts may be made in an active-area of display 108 (to accommodate camera 110).

While illustrated as being disposed in the top right bezel of folding device 100, it is understood that camera 110 may be integrated into any bezel of folding device 100. For instance, camera 110 may be integrated into any of the top-left, bottom-left, or bottom-right bezels. Similarly, camera 110 may be integrated into the left bezel or the right bezel. In some examples, folding device 100 may include multiple camera that may be integrated into a same bezel (e.g., multiple cameras in the top-right bezel) or integrated into different bezels (e.g., a first camera in the top-left bezel and a second camera in the top-right bezel).

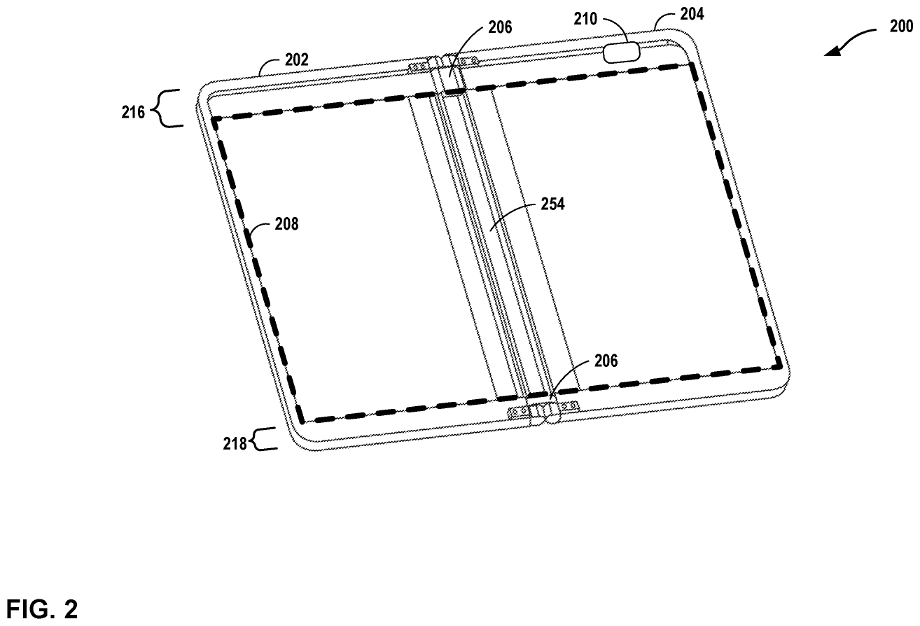

FIG. 2 is an angled view illustrating a folding device with a camera integrated into a bezel of a continuous display, in accordance with one or more aspects of this disclosure. Folding device 200 of FIG. 2 may be considered to be an example of folding device 100 of FIG. 1. Similarly, first assembly 202, second assembly 204, hinge assembly 206, continuous display 208, camera 210, top bezel 216, and bottom bezel 218 may respectively be considered examples of first assembly 102, second assembly 104, hinge assembly 106, camera 110, top bezel 116, and bottom bezel 118 of FIG. 1.

Continuous display 208 is shown as being transparent in FIG. 2 (e.g., only a perimeter of continuous display 208 is shown as a heavy broken line). As such, it can be seen that hinge assembly 206 includes cavity 254, into which a portion of continuous display 208 may reside when foldable device 200 is fully closed.

In accordance with one or more aspects of this disclosure, similar to camera 110 of folding device 100 of FIG. 1, camera 210 of folding device 200 may be located in top bezel 216 that forms a portion of a border of continuous display 208. In some examples, a dimension of camera 210 may be approximately equal to a dimension of top bezel 216. For instance, a dimension of top bezel 216 parallel to second axis 130B may be approximately equal (e.g., within 5%) to a dimension of camera 210 (e.g., an opening or aperture of camera 210) parallel to second axis 130B. Trim housing components may not be shown in FIG. 2.

FIGS. 3A-3C are schematic diagrams illustrating cross sections of a folding device with a camera integrated into a bezel of a continuous display, in accordance with one or more aspects of this disclosure. Folding device 300 of FIGS. 3A-3C may be considered to be an example of folding device 100 of FIG. 1. Similarly, first assembly 302, second assembly 304, hinge assembly 306, continuous display 308, camera 310, top bezel 316, trim housing 322, trim housing 324, opening 326, first axis 330A, and second axis 330B may respectively be considered examples of first assembly 102, second assembly 104, hinge assembly 106, continuous display 108, camera 110, top bezel 116, trim housing 122, trim housing 124, opening 126, first axis 130A, and second axis 130B of FIG. 1.

As shown in FIG. 3A, hinge assembly 306 includes clearance (e.g., a cutout, cavity, etc.) to receive at least a portion of continuous display 308 when device 300 is closed. As shown in FIG. 3C, when the folding device 300 is fully closed, an apex of the primary flexible segment (e.g., apex 309 of continuous display 308) is closer to the outer surface of the hinge assembly (e.g., outer surface 323 of hinge assembly 322) than a plane that is parallel to the first axis and a second axis (e.g., plane 350 that is parallel to first axis 316A and second axis 316B). By allowing at least a portion of continuous display 308 to recede when device 300 is fully closed, device 300 may avoid the need for a rotate and slide mechanism. In this way, the design of a foldable display device may be simplified.

FIGS. 4A-4F are schematic diagrams illustrating a layering of components that results in a camera integrated into a bezel of a continuous display, in accordance with one or more aspects of this disclosure. Folding device 400 of FIGS. 4A-4F may be considered to be an example of folding device 100 of FIG. 1. Similarly, second assembly 404 may be considered to be an example of second assembly 104 of FIG. 1.

As shown in FIG. 4A, enclosure 440 may represent a primary housing of second assembly 404 of folding device 400. Enclosure 440 may define opening 442. Dust seal 444 may be applied around opening 442. Lens glue 446 may be applied around, or partially around, dust seal 444. Lens 448 may be adhered to enclosure 440 via lens glue 446. As can be seen in FIG. 4D, enclosure 440 may include a recess or indentation configured to receive one or more other components, such as lens 448. Trim glue 450 may be applied to surfaces of enclosure 450. Continuous display 408 may be installed. Continuous display 408 may be an example of continuous display 108 of FIG. 1. Trim housing 424 may be adhered to enclosure 440 via trim glue 450. As shown in FIG. 4F, trim housing 424 may define opening 426. Trim housing 424 and opening 426 may be examples of trim housing 124 and opening 126 of FIG. 1. As can be seen in the example of FIG. 4F, trim housing 424 may cover all edges of lens 448 and an edge of continuous display 408 adjacent to lens 448.

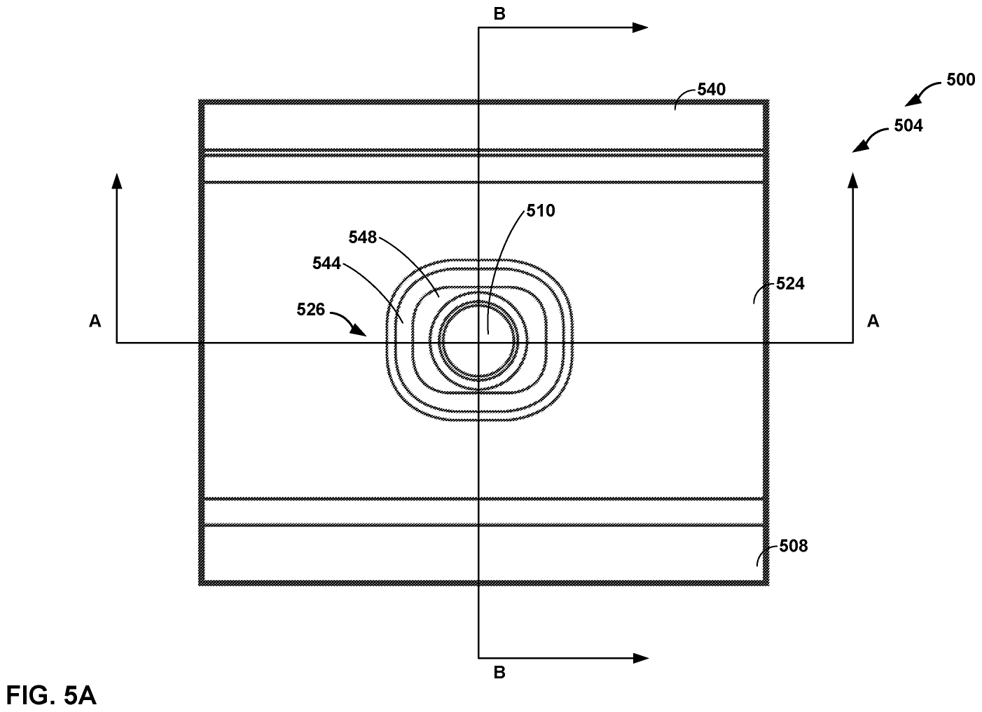

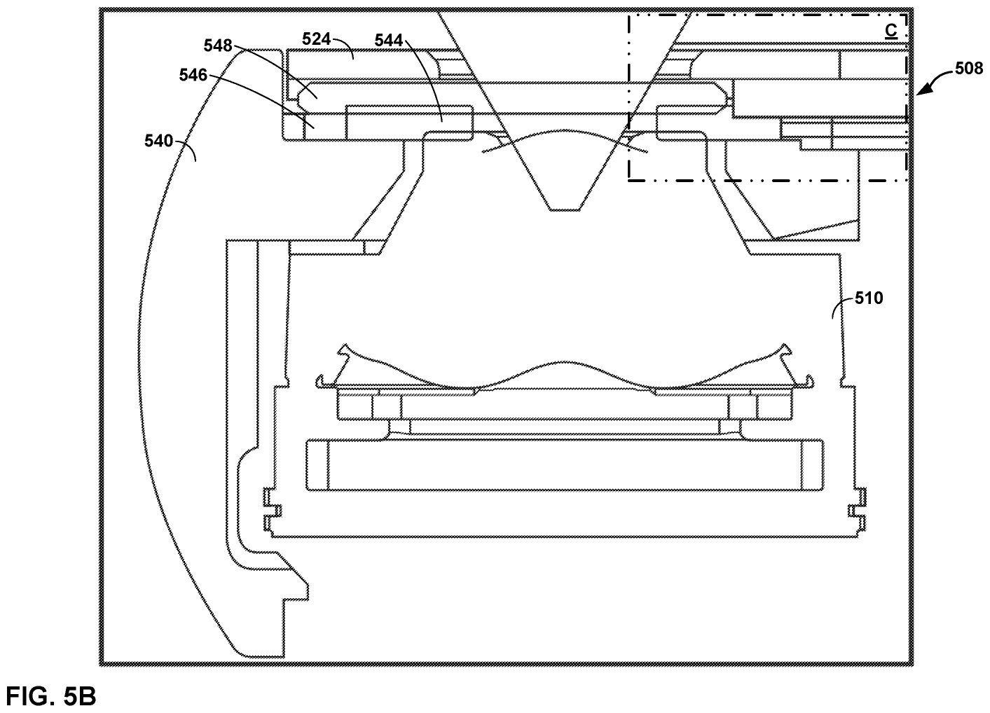

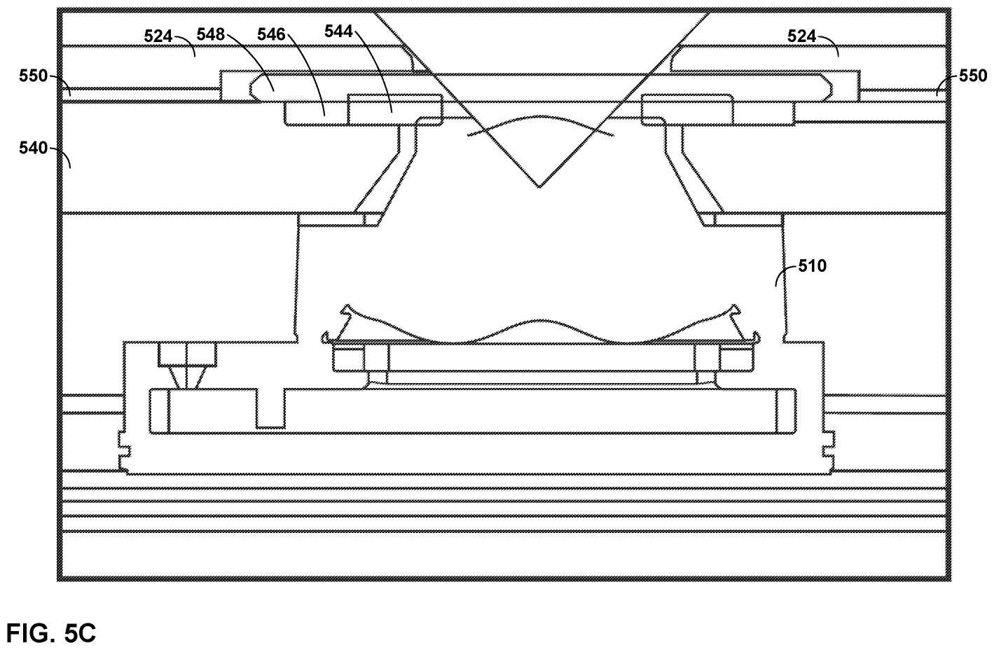

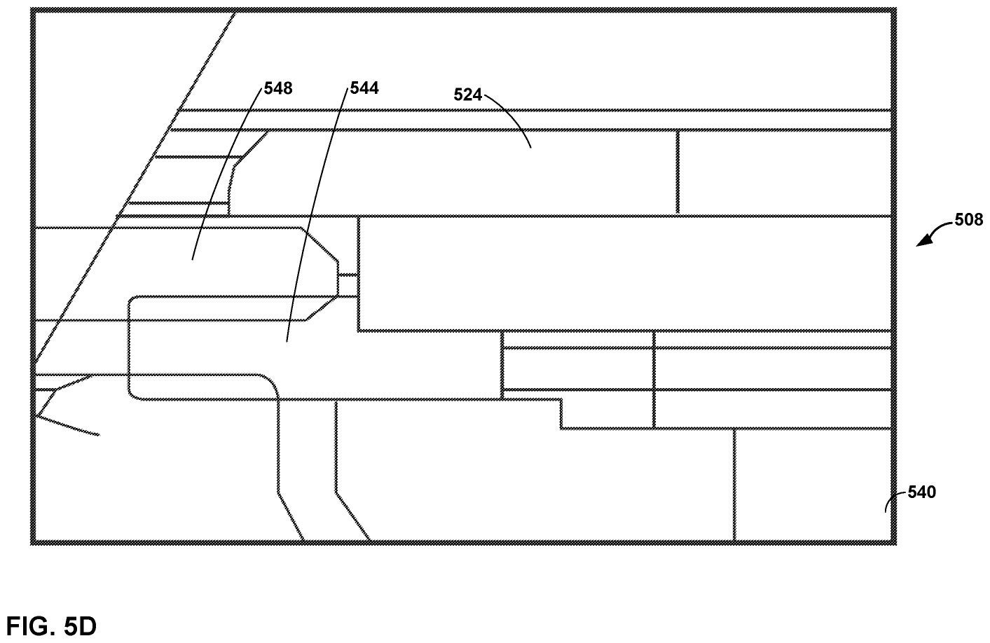

FIG. 5A is a schematic diagram illustrating an assembled camera integrated into a bezel of a continuous display of a folding device, in accordance with one or more aspects of this disclosure. Folding device 500 of FIGS. 5A-5D may be considered to be an example of folding device 100 of FIG. 1. Similarly, second assembly 504, continuous display 508, camera 510 may be considered to be examples of second assembly 104, continuous display 108, and camera 110 of FIG. 1.

FIG. 5B is a schematic illustrating a cross-section along line A-A of FIG. 5A, in accordance with one or more aspects of this disclosure. FIG. 5C is a schematic illustrating a cross-section along line B-B of FIG. 5A, in accordance with one or more aspects of this disclosure. FIG. 5D is an enlargement of area C of FIG. 5B, in accordance with one or more aspects of this disclosure.

Continuous display 508 may include a plurality of layers. As can be seen in FIGS. 5B and 5D, in some examples, a subset of the plurality of layers may be notched, or otherwise locally cut-back, proximate to camera 510. The locally cut-back area may be designed such that it only cuts back a sub-set of layers (e.g., a rear support, adhesive and/or cushion layers) of the foldable display (e.g., so that the active area is not affected). Such an arrangement may allow for dust seal 544 to be adhered to enclosure 440 partially under display 508, which may reduce the border dimension of the product outside the display active area. Dust seal 544 may be designed to be supportive of the remaining layers of display 508 that are not cut back.

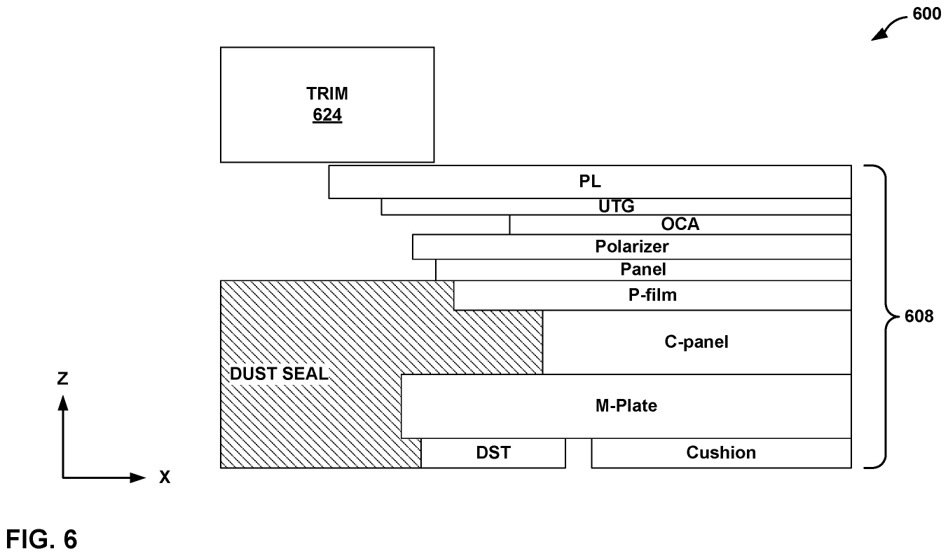

FIG. 6 is a schematic illustrating a cross section similar to FIG. 5D, in accordance with one or more aspects of this disclosure. Folding device 600 of FIG. 6 may be considered to be an example of folding device 100 of FIG. 1. Similarly, continuous display 608 and trim 624 may be considered to be examples of continuous display 108 and trim 124 of FIG. 1.

A shown in FIG. 6, continuous display 608 includes a plurality of layers. For instance, where continuous display 608 comprises an active-matrix organic light emitting diode (AMOLED) display panel, the plurality of layers may include one or more of a protection layer (PL), a ultra-thin glass layer (UTG), a polarizer layer, an AMOLED layer (e.g., that includes the light emitting elements), protective film layer (P-film), a cushion layer (C-panel), a metal stiffener (M-Plate), double sided tape (DST), and a cushion layer (Cushion).

As discussed above, in some examples, a subset of the plurality of layers of display 308 may be notched or otherwise cut-back proximate to camera that is located in the bezel of the continuous display. The subset of layers that are notched may include one or more layers located below the panel layer (e.g., in the z-axis). For instance, the subset of layers that are notched may include one or more the protective film layer (P-film), the cushion layer (C-panel), the metal stiffener (M-Plate), the double sided tape (DST), and the cushion layer (Cushion). In one specific example, the subset of layers includes the metal stiffener layer.

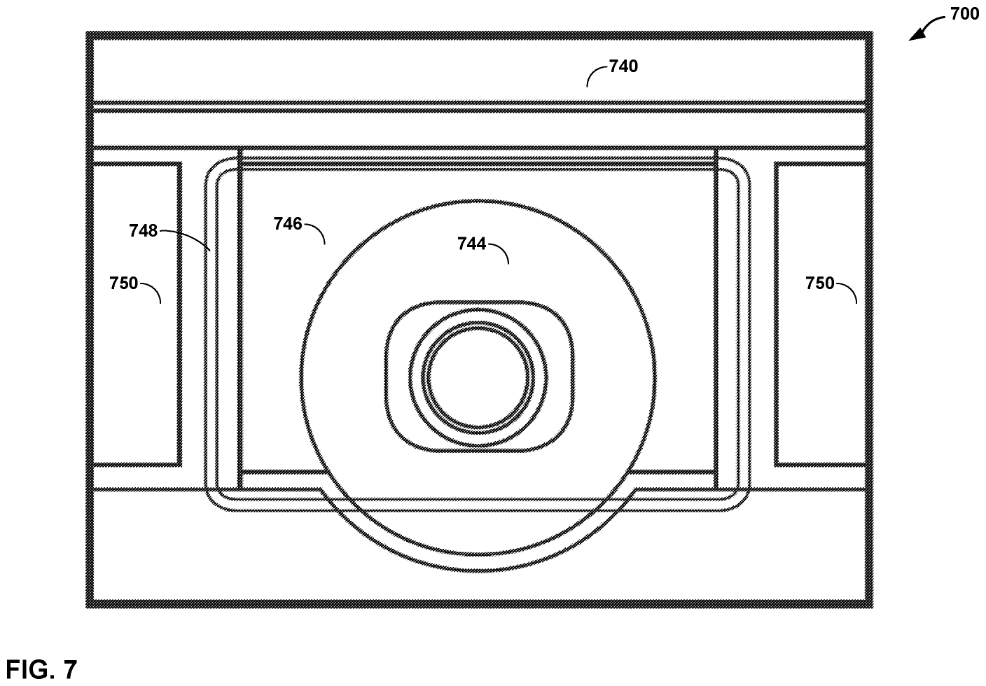

FIG. 7 is a schematic diagram illustrating an assembled camera integrated into a bezel of a continuous display of a folding device, in accordance with one or more aspects of this disclosure. Folding device 700 of FIG. 7 may be considered to be an example of folding device 500 of FIGS. 5A-5D. Similarly, enclosure 740, dust seal 744, lens adhesive 746, lens 748, and trim glue 750 may be considered to be examples of enclosure 540, dust seal 544, lens adhesive 546, lens 548, and trim glue 550 of FIGS. 5A-5D. In the example of FIG. 7, the trim and foldable display are both hidden to provide a better view of the other components.

Various aspects have been described in this disclosure. These and other aspects are within the scope of the following claims.

1. A folding computing device comprising:
a hinge assembly defining a first axis and a second axis;
a first assembly rotatably connected to the hinge assembly about the first axis;
a second assembly rotatably connected to the hinge assembly about the second axis, wherein, when the folding device is fully opened about the hinge assembly, an inner surface of the first assembly is coplanar with an inner surface of the second assembly;
a flexible continuous display spanning an inner surface of the first assembly and an inner surface of the second assembly; and
a camera having an aperture located in a bezel of the second assembly that borders the flexible continuous display.

2. The folding computing device of claim 1, wherein the flexible continuous display comprises an active-matrix organic light emitting diode (AMOLED) display panel comprising a plurality of layers.

3. The folding computing device of claim 2, wherein the plurality of layers of the AMOLED display panel comprises:
an AMOLED layer; and
a metal stiffener layer.

4. The folding computing device of claim 3, wherein a subset of the plurality of layers of the AMOLED display are notched proximate to the camera.

5. The folding computing device of claim 4, wherein the subset of the plurality of layers comprises the metal stiffener layer.

6. The folding computing device of claim 1, wherein the second assembly further comprises a trim housing component that forms the bezel of the second assembly, the trim component defining an opening via which the aperture of the camera receives light.

7. The folding computing device of claim 6, wherein the opening defined by the trim housing component is shaped as a discorectangle.

8. The folding computing device of claim 6, wherein the camera further comprises an image sensor and a lens, the lens disposed between the trim housing component and the image sensor.

9. The folding computing device of claim 8, wherein the lens is not decorated.

10. The folding computing device of claim 6, wherein the opening has a long dimension and a short dimension, and wherein the short dimension is parallel to the second axis.

11. The folding computing device of claim 10, wherein the short dimension of the opening is approximately equal to a dimension of the bezel parallel to the second axis.

12. The folding computing device of claim 1, further comprising:
mechanical components configured to connect the hinge assembly to the second assembly, wherein the mechanical component are located in a top hinge region.

13. The folding computing device of claim 12, wherein the top hinge region is not located under the flexible continuous display.

14. The folding computing device of claim 12, wherein a dimension of the bezel parallel to the second axis is greater than or equal to a dimension of the top hinge region parallel to the second axis.

15. The folding computing device of claim 1, wherein the flexible continuous display comprises an active-matrix organic light emitting diode (AMOLED) display panel comprising a plurality of layers, wherein the plurality of layers of the AMOLED display panel comprises:
an AMOLED layer; and
a metal stiffener layer,
wherein a subset of the plurality of layers of the AMOLED display are notched proximate to the camera, and wherein the subset of the plurality of layers comprises the metal stiffener layer.
